(19) United States
(12) Patent Application Publication
(10) Pub. No.: US 2005/0110027 A1
(43) Pub. Date: May 26, 2005

(54) LED lamp having heat dissipating portion

(76) Inventors: Seung Mo Park, Seoul (KR); Yong Chil Choi, Suwon (KR); Yoon Sung Na, Yongin (KR); Kyung Taeg Han, Hwasung-gun (KR)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/873,298

(22) Filed: Jun. 23, 2004

(30) Foreign Application Priority Data
Nov. 25, 2003 (KR) 2003-83998

(51) Int. Cl. H01L 27/15; H01L 31/0203

(52) U.S. Cl. 257/81; 257/99; 257/433; 257/706; 257/787

(57) ABSTRACT

Disclosed is an LED (Light Emitting Diode) lamp including a light emitting diode having first and second electrodes; a first lead frame, provided with a cup portion formed at one end thereof and a first lead portion extended from the cup portion to the other end thereof, and electrically connected to the first electrode; a second lead frame, provided with a diode connecting portion adjacent to the cup portion and a second lead portion adjacent to the first lead portion, spaced from the first lead, and electrically connected to the second electrode; a mold for sealing the light emitting diode, the cup and diode connecting portion; and a heat dissipating portion, having a designated area, formed on at least one selected from the group consisting of a lower portion of the cup portion, a lower portion of the diode connecting portion, the first lead portion and the second lead portion.

### BACKGROUND OF THE INVENTION

1. Field of the Invention

The present invention relates to an LED (Light Emitting Diode) lamp, and more particularly to an LED lamp having a heat dissipating portion installed on at least one of two lead frames for dissipating heat generated from the inside of a mold therethrough, thus improving quality and reliability of an LED product.

2. Description of the Related Art

Recently, light emitting apparatuses have been remarkably developed. Particularly, LEDs (Light Emitting Diodes) have various characteristics, such as compact size, low power consumption, high reliability, etc., thereby being used as light sources for displaying an image. Main materials of the LEDs, which are practically used, are 5-grouped elements such as AlGaAs, GaAlP, InGaAlP, etc. 3 to 5-grouped compound semiconductors using As and P are used to emit red, orange, yellow, and green colors, and GaN-based compound semiconductors are used to emit green and blue colors, and ultraviolet lights. As such LEDs are making rapid progress now toward high luminance, the LEDs are used for various purposes, for example, as an electric sign for displaying total natural colors or a light source for communication.

FIG. 1a is a perspective view of a conventional LED lamp. FIG. 1b is a front view of the conventional LED lamp. With reference to FIGS. 1a and 1b, a conventional LED lamp 10 comprises a light emitting diode 11 having first and second electrodes, a first lead frame 12, provided with a cup formed at one end thereof for receiving the light emitting diode 11 and electrically connected to the first electrode of the light emitting diode 11, including a cup portion 121 located on the inside of a mold 15, which will be described below, and a lead portion 122 located on the outside of the mold 15, a second lead frame 13, electrically connected to the second electrode of the light emitting diode 11, including a diode connecting portion 131 located on the inside of the mold 15 and a lead portion 132 located on the outside of the mold 15, and the mold 15 for sealing the light emitting diode 11, the cup portion 121 of the first lead frame 12 and the diode connecting portion 131 of the second lead frame 13. The mold 15 is made of epoxy having low heat conductivity.

As shown in FIG. 1, regions of the first and second lead frames 12 and 13 of the conventional LED lamp 10, which are located on the inside of the mold 15, i.e., the diode reception portion 121 and the diode connecting portion 131, have a large area. Heat generated by the operation of the light emitting diode 11 is transmitted to the first and second lead frames 12 and 13. Since the large-sized portions of the first and second lead frames 12 and 13, such as the diode reception portion 121 and the diode connecting portion 131, are located within the mold 15 made of epoxy having the low heat conductivity, it is difficult to dissipate the heat from the inside of the mold 15 to the outside of the mold 15. Since the dissipation of the heat to the outside of the mold 15 is not effectively achieved, efficiency of the light emitting diode 11 is reduced, thereby preventing the LED lamp 10 from generating light having desired quality and shortening a life span of the LED lamp 10.

Further, since the large-sized portions of the first and second lead frames 12 and 13, i.e., the diode reception portion 121 and the diode connecting portion 131, are located in the mold 15, the mold 15 must has a large volume, thereby increasing an amount of epoxy consumed and increasing a production cost of the LED lamp 10.

Accordingly, there is required a novel LED lamp, which easily dissipates heat generated from a light emitting diode to the outside of a mold and reduces an amount of epoxy consumed to produce the mold.

### SUMMARY OF THE INVENTION

Therefore, the present invention has been made in view of the above problems, and it is an object of the present invention to provide an LED lamp, which easily dissipates heat generated from a light emitting diode, when the lamp is operated, to the outside of a mold so as to improve optical quality of the LED lamp and elongate a life span of the LED lamp, and reduces an amount of epoxy consumed to produce the mold so as to reduce a production cost of an LED lamp product.

In accordance with of the present invention, the above and other objects can be accomplished by the provision of an LED (Light Emitting Diode) lamp comprising: a light emitting diode having first and second electrodes; a first lead frame, provided with a cup portion formed at one end thereof for receiving the light emitting diode and a first lead portion extended from the cup portion to the other end thereof, and electrically connected to the first electrode of the light emitting diode; a second lead frame, provided with a diode connecting portion adjacent to the cup portion and a second lead portion adjacent to the first lead portion, spaced from the first lead frame by a designated distance, and electrically connected to the second electrode of the light emitting diode; a mold for sealing the light emitting diode, the cup portion, and the diode connecting portion; and a heat dissipating portion, having a designated area, formed on at least one selected from the group consisting of a lower portion of the cup portion, a lower portion of the diode connecting portion, the first lead portion and the second lead portion.

Preferably, the heat dissipating portion is made of the same material as that of the first lead frame and the second lead frame, formed on at least one of the lower portion of the cup portion and the lower portion of the diode connecting portion, and exposed to the outside through a surface of the mold.

In accordance with one aspect of the present invention, the heat dissipating portion is extended from the lower portion of the cup portion to some position on the first lead portion, or the lower portion of the diode connecting portion to some position on the second lead portion.

In accordance with another aspect of the present invention, the heat dissipating portion is spaced from a lower surface of the mold by a designated distance and formed on at least one of the first lead portion and the second lead portion.

In accordance with yet another aspect of the present invention, the heat dissipating portion is formed in the shape of a polyprism or a cylinder in parallel with the lead frames.

In accordance with yet another aspect of the present invention, the heat dissipating portion is formed in the shape of a flat plate in parallel with the lead frames.

In accordance with yet another aspect of the present invention, the heat dissipating portion includes at least two flat plates crossing each other in parallel with the lead frames.

### BRIEF DESCRIPTION OF THE DRAWINGS

The above and other objects, features and other advantages of the present invention will be more clearly understood from the following detailed description taken in conjunction with the accompanying drawings, in which:

FIG. 1a is a perspective view of a conventional LED lamp;

FIG. 1b is a front view of the conventional LED lamp;

FIG. 2a is a front view of an LED lamp in accordance with a first embodiment of the present invention;

FIG. 2b is a perspective view of the LED lamp, which is viewed from the bottom, in accordance with the first embodiment;

FIG. 3a is a front view of each of LED lamps in accordance with second to fourth embodiments of the present invention;

FIG. 3b is a perspective view of the LED lamp, which is viewed from the bottom, in accordance with the second embodiment of the present invention;

FIG. 3c is a perspective view of the LED lamp, which is viewed from the bottom, in accordance with the third embodiment of the present invention;

FIG. 3d is a perspective view of the LED lamp, which is viewed from the bottom, in accordance with the fourth embodiment of the present invention;

FIG. 4a is a front view of an LED lamp in accordance with a fifth embodiment of the present invention;

FIG. 4b is a perspective view of the LED lamp, which is viewed from the bottom, in accordance with the fifth embodiment of the present invention;

FIG. 5a is a front view of an LED lamp in accordance with a sixth embodiment of the present invention;

FIG. 5b is a perspective view of the LED lamp, which is viewed from the bottom, in accordance with the sixth embodiment of the present invention;

FIG. 6a is a front view of an LED lamp in accordance with a seventh embodiment of the present invention; and

FIG. 6b is a perspective view of the LED lamp, which is viewed from the bottom, in accordance with the seventh embodiment of the present invention.

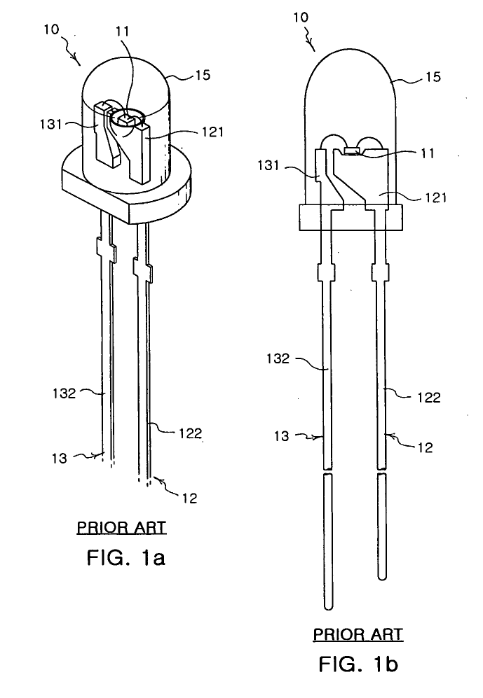

### DESCRIPTION OF THE PREFERRED EMBODIMENTS

Now, preferred embodiments of the present invention will be described in detail with reference to the annexed drawings.

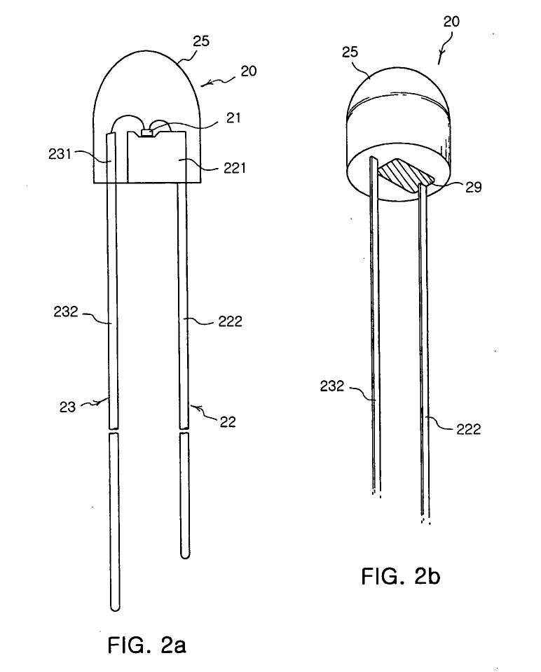

FIG. 2a is a front view of an LED lamp in accordance with a first embodiment of the present invention. FIG. 2b is a perspective view of the LED lamp, which is viewed from the bottom, in accordance with the first embodiment. As shown in FIG. 2a, an LED lamp 20 in accordance with the first embodiment of the present invention comprises a light emitting diode 21 having first and second electrodes; a first lead frame 22, provided with a cup portion 221 formed at one end thereof for receiving the light emitting diode 21 and a first lead portion 222 extended from the cup portion 221 to the other end thereof, and electrically connected to the first electrode of the light emitting diode 21; a second lead frame 23, provided with a diode connecting portion 231 adjacent to the cup portion 221 and a second lead portion 232 adjacent to the first lead portion 222, spaced from the first lead frame 22 by a designated distance, and electrically connected to the second electrode of the light emitting diode 21; a mold 25 for sealing the light emitting diode 21, the cup portion 221, and the diode connecting portion 231.

Preferably, the cup portion 221 and the diode connecting portion 231 have a comparatively small length. In the first embodiment of the present invention as shown in FIG. 2a, a lower surface of the cup portion 221 has the same level as that of a lower surface of the mold 25, thereby being exposed to the outside. Preferably, the cup portion 221 of the first lead frame 22 is designed such that the lower surface of the cup portion 221 has the same area as that of the upper surface of the cup portion 221. Here, the exposed lower surface of the cup portion 221 through the lower surface of the mold 25 serves as a heat dissipating portion, and will be described in detail with reference to FIG. 2b.

In accordance with the first embodiment of the present invention as shown in FIG. 2b, the exposed lower surface of the cup portion 221 through the lower surface of the mold 25 serves as the heat dissipating portion 29. In order to obtain excellent heat dissipating effects, it is preferable that the exposed lower surface of the cup portion 221 has a comparatively large area. The present invention is not limited to the above-described first embodiment. In the first embodiment of the present invention, the heat dissipating portion 29 is formed in the first lead frame 22. However, a heating dissipating portion may be formed in the second lead frame 23. If the heating dissipating portion is formed in the second lead frame 23, the exposed lower surface of the diode connecting portion 231 through the lower surface of the mold 25 serves as the heat dissipating portion 29. Further, the heat dissipating portion can be formed both in the first and second lead frames 22 and 23.

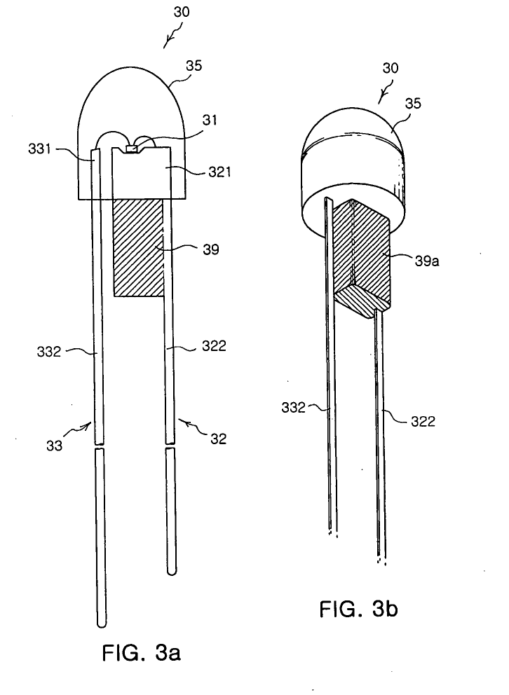

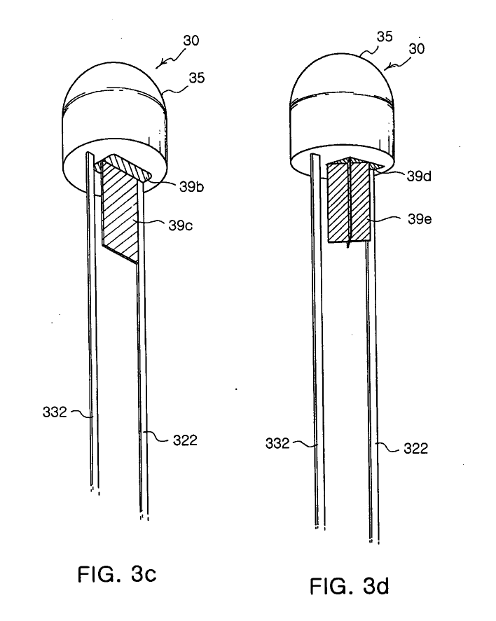

FIG. 3a is a front view of each of LED lamps in accordance with second to fourth embodiments of the present invention. As shown in FIG. 3a, each of the LED lamps 30 in accordance with the second to fourth embodiments of the present invention comprises a light emitting diode 31 having first and second electrodes; a first lead frame 32, provided with a cup portion 321 formed at one end thereof for receiving the light emitting diode 31 and a first lead portion 322 extended from the cup portion 321 to the other end thereof, and electrically connected to the first electrode of the light emitting diode 31; a second lead frame 33, provided with a diode connecting portion 331 adjacent to the cup portion 321 and a second lead portion 332 adjacent to the first lead portion 322, spaced from the first lead frame 32 by a designated distance, and electrically connected to the second electrode of the light emitting diode 31; a mold 35 for sealing the light emitting diode 31, the cup portion 321, and the diode connecting portion 331; and a head dissipating portion 39 including a lower surface of the cup portion 321 exposed to the outside through a lower surface of the mold 35 and a part directly connected to the lower surface of the cup portion 321 exposed to the outside through a lower surface of the mold 35. The heat dissipating portion 39 is formed in the shape of a polyprism, a cylinder, a flat plate or at least two flat plates crossing each other in parallel with the lead frames. FIGS. 3b to 3d are respectively perspective views of the LED lamps, which are viewed from the bottom, in accordance with the second to fourth embodiments of the present invention.

FIG. 3b is a perspective view of the LED lamp, which is viewed from the bottom, in accordance with the second embodiment of the present invention. In the second embodiment of the present invention, a heat dissipating portion 39a is obtained by extending the cup portion 321 to the outside of the mold 35 by a designated length. That is, the heat dissipating portion 39a is obtained by extending a lower surface of the cup portion 321, exposed to the outside through the lower surface of the mold 35, along the lead portion 322 of the first lead frame 32 by the designated length. In the second embodiment, it is preferable that the heat dissipating portion 39a is made of the same material as that of the first lead frame 32 provided with the heat dissipating portion 39a and formed integrally with the first lead frame 32. The heat dissipating portion 39a of the second embodiment of the present invention has a larger area, which is exposed to the outside, than that of the heat dissipating portion 29 of the first embodiment, thereby more improving heat dissipating effects. The present invention is not limited to the above-described second embodiment. In the second embodiment of the present invention, the heat dissipating portion 39a is formed in the first lead frame 32. However, the heating dissipating portion 39a may be formed in the second lead frame 33, or both in the first and second lead frames 32 and 33, in accordance with the size of the LED lamp 30.

FIG. 3c is a perspective view of the LED lamp, which is viewed from the bottom, in accordance with the third embodiment of the present invention. In the third embodiment of the present invention, a heat dissipating portion includes a lower surface 39b of the cup portion 321, exposed to the outside through the lower surface of the mold 35, and a flat plate 39c directly connected to the lower surface 39b. In the third embodiment, it is preferable that the flat plate 39c of the heat dissipating portion is made of the same material as that of the first lead frame 32 provided with the heat dissipating portion and formed integrally with the first lead frame 32. The flat plate 39c of the heat dissipating portion may contact or may not contact the lead portion 322 of the first lead frame 32. The number of the flat plates 39c is not limited to one. In the third embodiment of the present invention, the heat dissipating portion is formed in the first lead frame 32. However, the heating dissipating portion may be formed in the second lead frame 33, or both in the first and second lead frames 32 and 33, in accordance with the size of the LED lamp 30.

FIG. 3d is a perspective view of the LED lamp, which is viewed from the bottom, in accordance with the fourth embodiment of the present invention. In the fourth embodiment of the present invention, a heat dissipating portion includes a lower surface 39d of the cup portion 321, exposed to the outside through the lower surface of the mold 35, and two flat plates 39e, which cross each other, directly connected to the lower surface 39d. In the fourth embodiment in the same manner as the third embodiment, it is preferable that the flat plates 39e of the heat dissipating portion are made of the same material as that of the first lead frame 32 provided with the heat dissipating portion and formed integrally with the first lead frame 32. The flat plates 39e of the heat dissipating portion may contact or may not contact the lead portion 322 of the first lead frame 32. The number of the flat plates 39e is not limited to two, and the flat plates 39e need not cross each other as shown in FIG. 3d. In the fourth embodiment of the present invention in the same manner as the third embodiment, the heat dissipating portion may be formed in the second lead frame 33, or both in the first and second lead frames 32 and 33, in accordance with the size of the LED lamp 30.

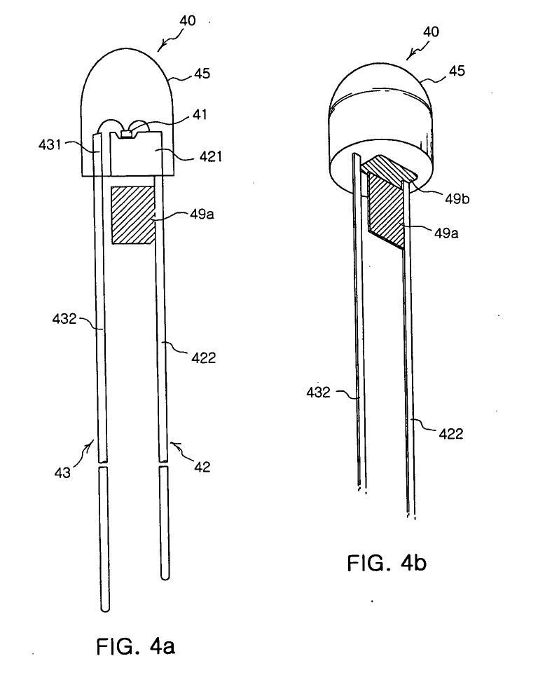

FIG. 4a is a front view of an LED lamp in accordance with a fifth embodiment of the present invention. As shown in FIG. 4a, the LED lamp 40 in accordance with the fifth embodiment of the present invention comprises a light emitting diode 41 having first and second electrodes; a first lead frame 42, provided with a cup portion 421 formed at one end thereof for receiving the light emitting diode 41 and a first lead portion 422 extended from the cup portion 421 to the other end thereof, and electrically connected to the first electrode of the light emitting diode 41; a second lead frame 43, provided with a diode connecting portion 431 adjacent to the cup portion 421 and a second lead portion 432 adjacent to the first lead portion 422, spaced from the first lead frame 42 by a designated distance, and electrically connected to the second electrode of the light emitting diode 41; a mold 45 for sealing the light emitting diode 41, the cup portion 421, and the diode connecting portion 431; and a heat dissipating portion including a lower surface 49b of the cup portion 421 exposed to the outside through the lower surface of the mold 45, and a part 49a spaced from the lower surface of the mold 45 by a designated distance and formed integrally with the first lead frame 42. FIG. 4b is a perspective view of the LED lamp 40 in accordance with the fifth embodiment of the present invention.

FIG. 4b is a perspective view of the LED lamp 40, which is viewed from the bottom, in accordance with the fifth embodiment of the present invention. In the fifth embodiment, a flat-type heat dissipating portion 49a is located below a lower surface 49b of the cup portion 421 exposed to the outside through the lower surface of the mold 45, and directly connected to and formed integrally with the lead portion 422 of the first lead frame 42. The flat-type heat dissipating portion 49a of the fifth embodiment is spaced from the lower surface 49b of the cup portion 421, exposed to the outside through the lower surface of the mold 45, by a designated distance, thereby having heat dissipating effects slightly lower than those of the earlier described other embodiments. The number of the flat-type heat dissipating portions 49a is not limited to one. Further, the flat plate 49a may have various shapes.

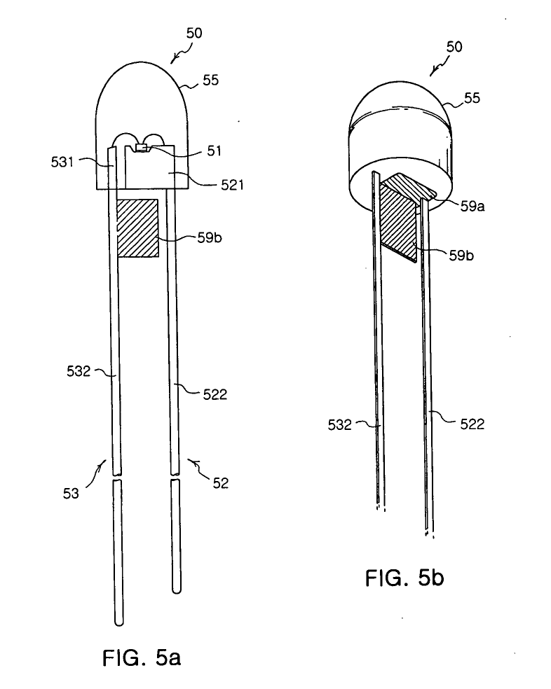

FIG. 5a is a front view of an LED lamp in accordance with a sixth embodiment of the present invention. As shown in FIG. 5a, the LED lamp 50 in accordance with the sixth embodiment of the present invention comprises a light emitting diode 51 having first and second electrodes; a first lead frame 52, provided with a cup portion 521 formed at one end thereof for receiving the light emitting diode 51 and a first lead portion 522 extended from the cup portion 521 to the other end thereof, and electrically connected to the first electrode of the light emitting diode 51; a second lead frame 53, provided with a diode connecting portion 531 adjacent to the cup portion 521 and a second lead portion 532 adjacent to the first lead portion 522, spaced from the first lead frame 52 by a designated distance, and electrically connected to the second electrode of the light emitting diode 51; a mold 55 for sealing the light emitting diode 51, the cup portion 521, and the diode connecting portion 531; and a heat dissipating portion including a first heat dissipating portion (59a of FIG. 5b) being a lower surface of the cup portion 521, exposed to the outside through a lower surface of the mold 55, and a second heat dissipating portion 59b spaced from the lower surface of the mold 55 by a designated distance and formed integrally with the lead portion 532 of the second lead frame 53.

FIG. 5b is a perspective view of the LED lamp, which is viewed from the bottom, in accordance with the sixth embodiment of the present invention. In the sixth embodiment, the heat dissipating portion includes the first heat dissipating portion 59a, which is the lower surface of the cup portion 521, exposed to the outside through the lower surface of the mold 55, and the second heat dissipating portion 59b formed integrally with the lead portion 532 of the second lead frame 53. The sixth embodiment of the present invention is a combination of the earlier-described first and fifth embodiments. The heat dissipating portion of the sixth embodiment includes two heating dissipating portions, i.e., the first and second dissipating portions 59a and 59b, thereby having more improved heat dissipating effects. In the sixth embodiment, the first heat dissipating portion can be formed on the lower surface of the diode connecting portion and the second heat dissipating portion can be formed on the first lead portion 522 of the first lead frame 52.

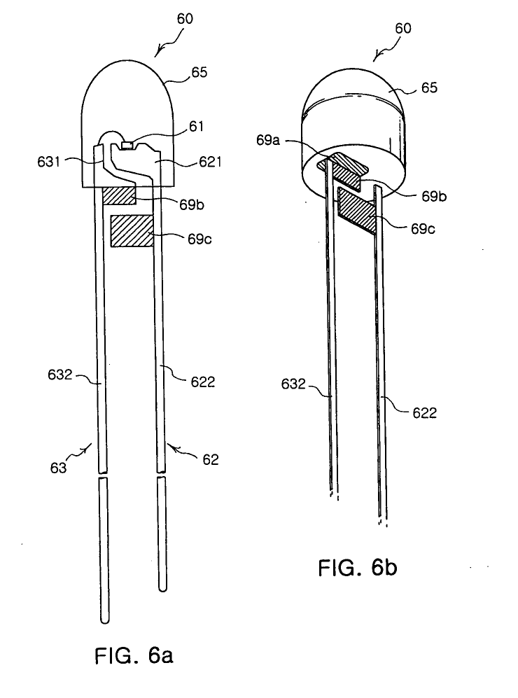

FIG. 6a is a front view of an LED lamp in accordance with a seventh embodiment of the present invention. As shown in FIG. 6a, the LED lamp 60 in accordance with the seventh embodiment of the present invention comprises a light emitting diode 61 having first and second electrodes; a first lead frame 62, provided with a cup portion 621 formed at one end thereof for receiving the light emitting diode 61 and a first lead portion 622 extended from the cup portion 621 to the other end thereof, and electrically connected to the first electrode of the light emitting diode 61; a second lead frame 63, provided with a diode connecting portion 631 adjacent to the cup portion 621 and a second lead portion 632 adjacent to the first lead portion 622, spaced from the first lead frame 62 by a designated distance, and electrically connected to the second electrode of the light emitting diode 61; a mold 65 for sealing the light emitting diode 61, the cup portion 621, and the diode connecting portion 631; and a heat dissipating portion including a lower surface (69a of FIG. 6b) of the diode connecting portion 631, exposed to the outside through a lower surface of the mold 65, a flat plate 69b directly connected to the exposed lower surface 69a of the diode connecting portion 631, and a flat plate 69c spaced from the lower surface of the mold 65 by a designated distance and connected to the first lead frame 62.

FIG. 6b is a perspective view of the LED lamp, which is viewed from the bottom, in accordance with the seventh embodiment of the present invention. In the seventh embodiment, the heat dissipating portion includes the lower surface 69a of the diode connecting portion 631, exposed to the outside through the lower surface of the mold 65, the flat plate 69b directly connected to the exposed lower surface 69a of the diode connecting portion 631, and the flat plate 69c spaced from the lower surface of the mold 65 by the designated distance and connected to the first lead frame 62. The seventh embodiment of the present invention is a combination of the earlier-described third and fifth embodiments. The heat dissipating portion of the seventh embodiment includes three heating dissipating portions, thereby having more improved heat dissipating effects.

An LED lamp in accordance with one of the above-described various embodiments of the present invention comprises a cup portion and a diode connecting portion of lead frames located in a mold, having a small area, and a heat dissipating portion having a large area, thereby easily dissipating heat generated from the inside of the mold to the outside of the mold. Further, since the above portions located in the mold have a reduced size, the LED lamp of the present invention reduces an amount of epoxy consumed to produce the mold of the LED lamp.

As apparent from the above descriptions of various embodiments, the present invention provides an LED lamp, which easily dissipates heat generated from a light emitting diode, when the LED lamp is operated, to the outside of a mold through a heat dissipating portion located on the outside of the mold, thus improving optical quality and lengthening a life span of an LED lamp product. Further, since portions of lead frames of the LED lamp, located in the mold, have a reduced area, the LED lamp of the present invention reduces an amount of epoxy consumed to produce the mole of the LED lamp, thereby reducing production cost of the LED lamp and increasing competitiveness in terms of price.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. An LED (Light Emitting Diode) lamp comprising:
a light emitting diode having first and second electrodes;
a first lead frame, provided with a cup portion formed at one end thereof for receiving the light emitting diode and a first lead portion extended from the cup portion to the other end thereof, and electrically connected to the first electrode of the light emitting diode;
a second lead frame, provided with a diode connecting portion adjacent to the cup portion and a second lead portion adjacent to the first lead portion, spaced from the first lead frame by a designated distance, and electrically connected to the second electrode of the light emitting diode;
a mold for sealing the light emitting diode, the cup portion, and the diode connecting portion; and
a heat dissipating portion, having a designated area, formed on at least one selected from the group consisting of a lower portion of the cup portion, a lower portion of the diode connecting portion, the first lead portion and the second lead portion.

2. The LED lamp as set forth in claim 1,
wherein the heat dissipating portion is made of the same material as that of the first lead frame and the second lead frame.

3. The LED lamp as set forth in claim 1,
wherein the heat dissipating portion is formed on at least one of the lower portion of the cup portion and the lower portion of the diode connecting portion, and exposed to the outside through a surface of the mold.

4. The LED lamp as set forth in claim 1,
wherein the heat dissipating portion is extended from the lower portion of the cup portion to some position on the first lead portion.

5. The LED lamp as set forth in claim 1,
wherein the heat dissipating portion is extended from the lower portion of the diode connecting portion to some position on the second lead portion.

6. The LED lamp as set forth in claim 1,
wherein the heat dissipating portion is spaced from a lower surface of the mold by a designated distance and formed on at least one of the first lead portion and the second lead portion.

7. The LED lamp as set forth in claim 1,
wherein the heat dissipating portion is formed in the shape of a polyprism or a cylinder in parallel with the lead frames.

8. The LED lamp as set forth in claim 1,
wherein the heat dissipating portion is formed in the shape of a flat plate in parallel with the lead frames.

9. The LED lamp as set forth in claim 1,
wherein the heat dissipating portion includes at least two flat plates crossing each other in parallel with the lead frames.
